(19) United States
(12) Patent Application Publication
(10) Pub. No.: US 2008/0142969 A1
(43) Pub. Date: Jun. 19, 2008

(54) MICROBALL MOUNTING METHOD AND MOUNTING DEVICE

(75) Inventor: Masakazu Hakuno, Beppu-shi (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/953,173

(22) Filed: Dec. 10, 2007

(30) Foreign Application Priority Data
Dec. 15, 2006 (JP) 2006-337769

(51) Int. Cl. H01L 21/60; H01L 23/498; H01R 43/02

(52) U.S. Cl. 257/738; 438/613; 29/877; 257/E21.51; 257/E23.069

(57) ABSTRACT

The objective of the invention is to present a mounting method by which mounting at higher densities and finer pitches can be handled so as to mount extremely small conductive balls. The mounting method of the present invention may be used to prepare porous base member 210 and mask set 220 with a 2-layer structure to be placed on base member 210, on which multiple through-holes 222a and 224a are created; vacuum adsorption is applied to base member 210 so as to form an adsorption surface on the surface of base member 210 that is exposed by through-holes 222a and 224a; microballs 260 are dropped into through-holes 222a and 224a of mask set 220; and microballs 260 are adsorbed by base member 210. Then, adsorbed microballs 260 are pressed against multiple terminal regions 108 that are formed on one surface of substrate 100 in order to transfer them there.

### FIELD OF THE INVENTION

The present invention pertains to a microball mounting method and mounting device used for mounting microballs onto a surface-mount type semiconductor device, such as a BGA or CPS package.

### BACKGROUND OF THE INVENTION

Due to the spread of portable telephones, portable computers, and other compact electronic devices, the demand is increasing for smaller and lighter installable semiconductor devices. To meet such demand, BGA packages and CSP packages have been developed and put to practical applications.

A BGA package or a CSP package is a surface-mount type of semiconductor device, wherein microballs for establishing external connections are mounted on one surface of the substrate of the package. Methods that utilize a suction head and methods that utilize a placement mask are available for this kind of microball mounting.

In the former method, as shown in FIG. 10 (a), substrate 3, on which semiconductor chip 1 is molded using resin 2, is mounted on a stage. A flux or solder paste is provided in terminal regions (electrode lands) 4 of substrate 3. Holes 7 for holding microballs (solder balls) 6 are created on suction head 5, whereby suction head 5 moves toward substrate 3 with microballs 6 held, and a pressure is applied to microballs 6 by suction head 5 in order to mount microballs 6 in terminal regions 4. This kind of microball mounting method is disclosed in Patent Reference 1 and Patent Reference 2, for example.

In the latter method, as shown in FIG. 10 (b) placement mask 10 is placed to face substrate 3. Through-holes 11 are created on placement mask 10 in the same pattern as that of terminal regions 4 of substrate 3. Microballs 6 supplied to placement mask 10 are dropped into through-holes 11 in order to mount them in terminal regions 4. Subsequently, microballs 6 and terminal regions 4 are connected together by means of reflow in order to form bump electrodes for external connections for a BGA or CSP package. This kind of microball mounting method is disclosed in Patent Reference 3, for example.

(Patent Reference 1) Japanese Kokai Patent Application No. 2001-332899

(Patent Reference 2) Japanese Kokai Patent Application No. Hei 8[1996]-335771

(Patent Reference 3) Japanese Kokai Patent Application No. 2004-327536

The above conventional microball mounting methods have the following problems. In methods that utilize a suction head, the vacuum holes for holding the microballs must be created on the suction head. The diameter of the vacuum hole is approximately ½ the diameter of the microball or larger; thus, as shown in FIG. 11 (a), when the diameter of the microball is 300 microns, the diameter of the vacuum hole is approximately 150 microns. When the diameter of the microball is large, the diameter and the pitch of the vacuum holes are large, so that the machining of the adsorption holes is relatively easy. However, when the density of the microballs is increased for a smaller device, the diameter of the microballs is reduced significantly to 180 microns or 100 microns, for example; the diameter of the vacuum holes must then be 90 microns or 50 microns, for example. Although the vacuum holes are machined using a drill when the suction head is made of a metal such as stainless steel, the machining becomes extremely difficult as the size of the vacuum holes is reduced. Even if machining is possible, the cost becomes prohibitive. In addition, when the suction head is made of a resin, burrs are created on its front surface as a result of the machining of the vacuum holes, resulting in degradation of the microball holding capability. As such, the mounting method utilizing the suction head is not suitable for mounting extremely small microballs at a fine pitch.

On the other hand, methods that utilize a placement mask are suitable for mounting extremely small microballs at a fine pitch in that, because the through-holes on the mask can be machined by means of etching or laser, the machining precision is high, and the cost is low. However, because no load can be applied to the microballs when mounting them onto the substrate, unlike with the suction-head-based method, it has the drawback when working on likely warped substrate. In the case of a semiconductor device such as a BGA or a CSP, because a resin for sealing the semiconductor chip is provided on the surface opposite the substrate where the microballs are mounted, the substrate is likely to warp due to the thermal contraction of the resin on the substrate. Especially in the case of a substrate on which multiple semiconductor chips are all resin-sealed together—as the volume of the resin increases, the substrate warps more significantly as a result. In addition, in the case of a rigid substrate as is the case with a multilayered substrate, the warping of the substrate becomes difficult to correct. For example, as shown in FIG. 11 (b), when placement mask 10 is placed to face substrate 3 with significant warpage, space S between them becomes greater than the diameter of the microballs. As a result, multiple microballs may be inserted into a single through-hole 11, or a microball dropped into through-hole 11 may not be positioned properly above a terminal region. Furthermore, because microballs 6 are not pressed against terminal regions 4, in other words, because they are simply placed on the flux, if the mounting positions deviate, the microballs may fall out due to vibrations while they are being carried to the subsequent reflow step.

The present invention is to solve these conventional problems, and its purpose is to present a conductive ball mounting method and a mounting device by which conductive balls can be mounted accurately in terminal regions of a substrate.

Furthermore, the present invention aims to present a conductive ball mounting method and a mounting device that are capable of handling mounting conductive balls at high densities and fine pitches as well as mounting extremely small conductive balls.

Furthermore, the present invention aims to present a conductive ball mounting method and a mounting device by which the yield of a semiconductor device can be improved and the manufacturing cost can be reduced.

### SUMMARY OF THE INVENTION

The mounting method of the present invention is for mounting conductive balls in multiple terminal regions formed on one side of a substrate. This method utilizes a porous base member having a first principal surface and a second principal surface opposite the first principal surface, and a mask member with multiple through-holes placed on the second principal surface. Suction is applied from the side of the first principal surface in order to hold conductive balls on the second principal surface of the base member. Conductive balls are supplied to the front surface of the mask member, by dropped them into the through-holes of the mask member. The conductive balls are held by the second principal surface of the base member, and are pressed against the multiple terminal regions formed on one side of the substrate in order to mount them there.

Preferably, the mask member includes a first-layer mask and a second-layer mask, wherein the second-layer mask is placed on the second principal surface of the base member, and the first-layer mask is placed on the second-layer mask. The conductive balls are placed below the front surface of the first-layer mask when the conductive balls are dropped through the through-holes of the first-layer and the second-layer masks and are partially exposed above the second-layer mask when the first-layer mask is removed from the second-layer mask. The conductive balls, partially exposed from the second-layer mask, are pressed against the terminal regions on one side of the substrate when mounting the conductive balls onto the substrate.

The mounting method further includes a step for transferring a flux to the front surfaces of the held conductive balls in order to mount the conductive balls to which the flux is transferred, in the corresponding terminal regions.

The conductive ball mounting device pertaining to the present invention has a porous base member having a first principal surface and a second principal surface opposite the first principal surface, a suction means that applies suction from the side of the first principal surface, a mask member that is placed on the second principal surface with multiple through-holes for exposing a portion of the second principal surface of the base member, a retaining means that holds a substrate with multiple terminal regions formed on one side of the substrate, and a pressing means that moves the retained substrate toward the base member in order to press the conductive balls that are held inside the through-holes on the second principal surface of the base member against the corresponding terminal regions on the substrate.

According to the present invention, because the conductive balls are held using the porous base member, and are in the through-holes, which are formed highly precisely by means of etching or laser, there is no need to create vacuum holes on the suction head, unlike in the past. Furthermore, because the conductive balls are supported by the base member, a load can be applied to the conductive balls to transfer them onto the substrate; and even when the substrate is warped, warpage of the substrate can be corrected so as to accurately mount the conductive balls to the terminal regions. As a result, extremely small conductive balls can be mounted at a fine pitch, problems and defects attributable to the mounting can be reduced, the yield of the semiconductor device can be improved, and manufacturing costs can be reduced.

### BRIEF DESCRIPTION OF THE DRAWINGS

FIG. 1 is a flow chart depicting the manufacturing process of the semiconductor device pertaining to an embodiment of the present invention.

FIG. 2 (a) is a plan view of a substrate on which semiconductor chips are mounted.

FIG. 2 (b) is a cross-sectional view of a single semiconductor chip on the substrate when it is molded using a resin.

FIG. 3 is a schematic diagram depicting the configuration of a microball mounting device.

FIG. 4 is a plan view of a mask set.

FIG. 5(a) and FIG. 5(b) are diagrams depicting the steps for mounting microballs in accordance with one embodiment of the present invention.

FIG. 6(a), FIG. 6(b), and FIG. 6(c) are diagrams depicting further steps for mounting microballs in accordance with one embodiment of the present invention.

FIG. 7(a) and FIG. 7(b) are diagrams depicting different steps for mounting microballs in accordance with one embodiment of the present invention.

FIG. 8(a), FIG. 8(b), FIG. 8(c), and FIG. 8(d) are diagrams showing a modification example of the mask set of the embodiment.

FIG. 9(a) and FIG. 9(b) are diagrams depicting the steps for mounting microballs in accordance with a second embodiment of the present invention.

FIG. 10(a) depicts a microball mounting method utilizing a suction head.

FIG. 10 (b) depicts a microball mounting method utilizing a placement mask.

FIG. 11 (a) depicts problems of a mounting method that utilizes a conventional suction head.

FIG. 11 (b) depicts problems of a mounting method that utilizes a placement mask.

### REFERENCE NUMERALS AND SYMBOLS AS SHOWN IN THE DRAWINGS

In the drawings, 100 represents a substrate, 102 a semiconductor chip, 104A, 104B, 104C, and 104D represents blocks, 106 represents bonding wire, 108 represents a terminal region, 110 represents mold resin, 200 represents a microball mounting device, 210 represents a base member, 220 represents a mask set, 222 represents a first-layer mask, 224 represents a second-layer mask, 222a and 224a represents through-holes, 230 represents a vacuum-pump device, 240 represents an suction plate, 250 represents a driving device, 260 represents microballs, 262 represents a placement member, 270 represents a flux, and 300, 310 and 320 represents tapered surfaces.

### DESCRIPTION OF THE EMBODIMENTS

A preferred embodiment of the present invention will be explained in detail below with reference to figures.

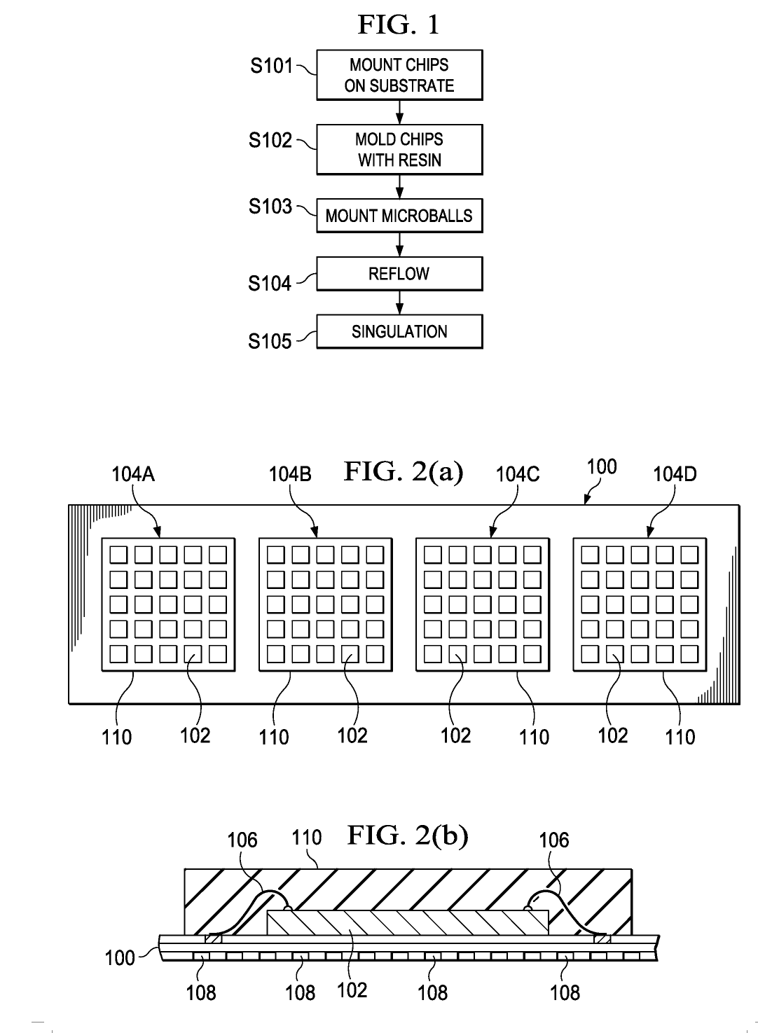

FIG. 1 shows the basic flow of a preferred manufacturing process of the semiconductor device pertaining to an embodiment of the present invention. In the present embodiment, a BGA package will be exemplified as the surface-mount type semiconductor device. First, multiple semiconductor chips are mounted on a substrate (Step S101), and the mounted semiconductor chips are molded using a resin (Step S102). Next, microballs are mounted in terminal regions (electrode lands) of the substrate (Step S103), the microballs and the terminal regions are joined by means of reflow (Step S104), and singulation is carried out in order to cut the substrate into individual semiconductor devices (Step S105).

FIG. 2 (a) is a plan view of the substrate on which the semiconductor chips are mounted, and FIG. 2 (b) is a cross-sectional view of a semiconductor chip mounted on the substrate. Although no particular restriction is imposed on the configuration of substrate 100, a multilayered substrate including an insulating layer and a wiring layer or a film substrate may be utilized to this end. In terms of the outer dimensions of substrate 100, the longer side is approximately 230 mm, and is the shorter side approximately 62 mm, for example. Semiconductor chips 102 are mounted in the form of a 2 dimensional array on the front surface of substrate 100. For example, 5×5 semiconductor chips are used to configure block 104A; and blocks 104B, 104C, and 104D of this kind are arranged on substrate 100 in the direction of the longer side.

As shown in FIG. 2 (b), a single semiconductor chip 102 is fixed to substrate 100 via an adhesive such as die-attach; and electrodes formed on the front surface of semiconductor chip 102 are connected to a wiring pattern formed on substrate 100 using bonding wires 106. Alternatively, semiconductor chip 102 may be of a flip chip mounting, wherein bump electrodes formed on its surface are placed face-down and connected to the wiring pattern of the substrate. The wiring pattern formed on the front surface of substrate 100 is connected to multiple terminal regions 108 that are formed as an array on the back surface of substrate 100 via internal wiring. As will be described later, terminal regions 108 connect the microballs so as to establish external connections for the BGA package, where several tens to several hundreds of microballs can be connected to a BGA package.

In addition, individual semiconductor chips 102 on substrate 100 are molded using resin 110. In the present embodiment, a single block comprising 5×5 semiconductor chips is molded at once. However, semiconductor chips 102 may be molded individually. In this embodiment, the height of resin 110 from the front surface of substrate 100 is approximately 450 microns, and the thickness of substrate 100 is approximately 240 microns.

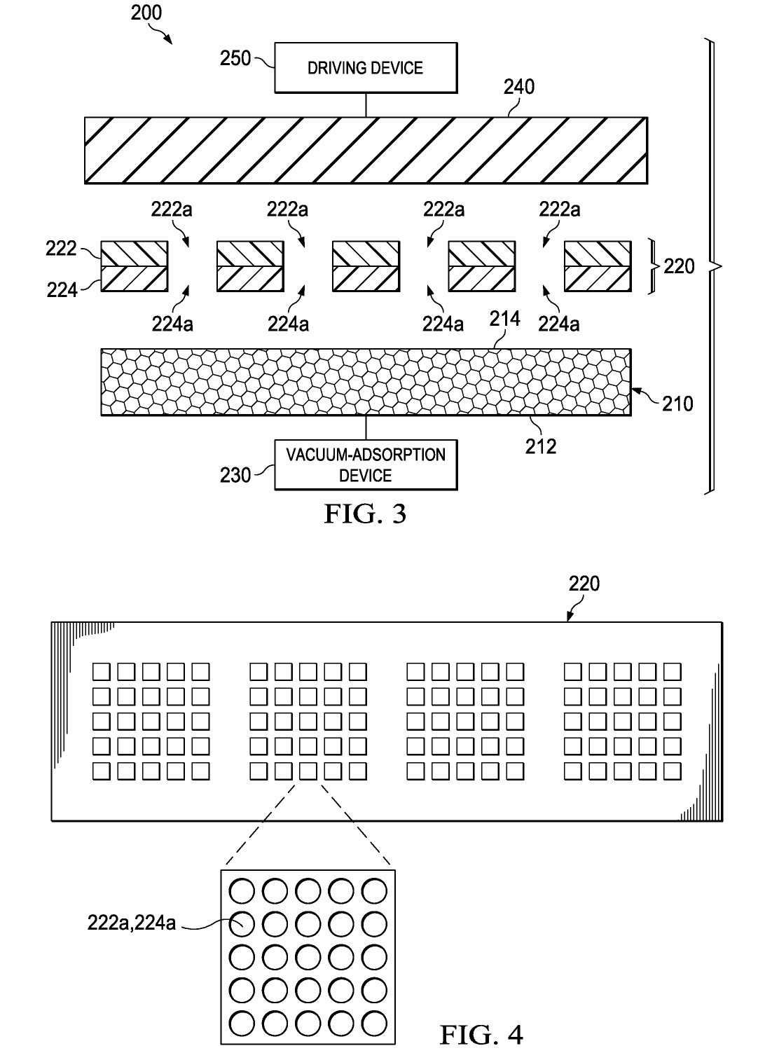

Next, mounting of the microballs will be explained. FIG. 3 is a schematic diagram of the configuration of the device used for mounting the microballs. Microball mounting device 200 is equipped with a porous base member 210, a mask set 220 to be placed on the base member 210, a vacuum-suction device such as a vacuum pump 230 for providing suction to the base member 200, a suction plate such as a vacuum chuck 240 for retaining a substrate on which the microballs are mounted, and a driving device 250 that moves the suction plate 240 toward or away from base member 210.

The base member 210 is configured using a porous body that is made of ceramic, metal, porous silicon, porous organic polymer, or porous resin. A porous ceramic base member can be obtained by baking alumina, for example; and a porous metallic base member can be obtained by baking stainless steel powders, for example. The side of lower surface 212 of the base member 210 is connected to the vacuum-suction device 230. Although detail is not illustrated, the side surfaces of base member 210 are airtight, and the top surface 214 of the base member 210 functions as a holding surface for holding the microballs. It is desirable that the top surface 214 of the base member 210 be flat in order to improve the holding capability.

FIG. 4 is a plan view of the mask set, wherein the mask area that corresponds to a single semiconductor chip is enlarged. Mask set 220 is created by aligning 2 layers of masks, that is, a first-layer mask 222 and a second-layer mask 224; and the first-layer mask 222 can be removed from the second-layer mask 224. Preferably, the second-layer mask 224 is fixed to the top surface 214 of the base member 210. Through-holes 222a and 224a are formed on the first-layer mask 222 and the second-layer mask 224 in the same pattern as the pattern of terminal regions 108 of substrate 100 where the microballs are mounted. FIG. 4 shows the pattern of through-holes 222a and 224a where 5×5 terminal regions are arranged on a single semiconductor chip as an example.

Preferably, the first-layer mask 222 and the second-layer mask 224 are formed with plated nickel layers by means of an additive method known in the art. When the additive method is utilized, through-holes can be created with high precision. Diameters D1 and D2 of through-holes 222a and 224a may be the same. The diameter of the microball is preferably 10 to 20 μm smaller than the through-hole diameter. For example, when diameter D of the microball is 100 μm, diameters D1 and D2 of the respective through-holes may be set to 110˜120 μm; and the pitch of the through-holes may be set to 0.3 mm. In addition, when the thickness of first-layer mask 222 is denoted as T1 and the thickness of second-layer mask 224 is denoted as T2, the relationship D<T1+T2 holds. Although thickness T1 of the first-layer mask and thickness T2 of the second-layer mask are the same in this embodiment, thicknesses T1 and T2 do not have to be the same.

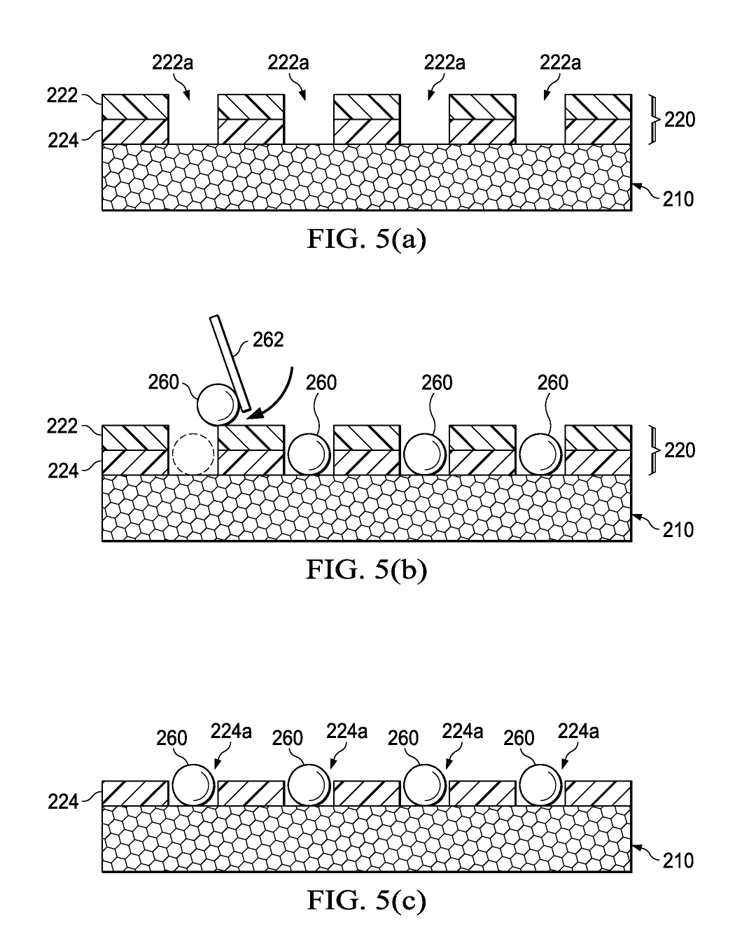

Next, a microball mounting method in accordance with the first embodiment will be explained. First, as shown in FIG. 5 (a), mask set 220 is placed on base member 210. Also, mask set 220 may be fixed to base member 210 in advance.

Next, as shown in FIG. 5 (b), microballs 260 are supplied onto mask set 220. Microball 260 is a conductive metal ball that is created by forming a solder layer on the surface of a simple solder body or a core made of copper or a resin. In the present embodiment, diameter D of mountable microball 260 may range from the extremely small size of 50 μm to 300 μm or so, for example. Microballs 260 are dropped into through-holes 222a and 224a by operating placement member 262 on mask set 220 in the horizontal direction. Because the thickness (T1+T2) of mask set 220 is greater than the diameter of microballs 260, dropped microballs 260 do not protrude from the top surface of mask set 220, therefore they do not come into contact with placement member 262. Because the vacuum-suction device 230 is operating simultaneously with the dropping of the microballs, microballs 260 are led to the exposed front surface of base member 210 by through-holes 222a and 224a and are held there.

Next, as shown in FIG. 5 (c), the first-layer mask 222 is removed from the second-layer mask 224. As the first-layer mask 222 is removed, the top portions of the microballs 260 are exposed from the front surface of the second-layer mask 224.

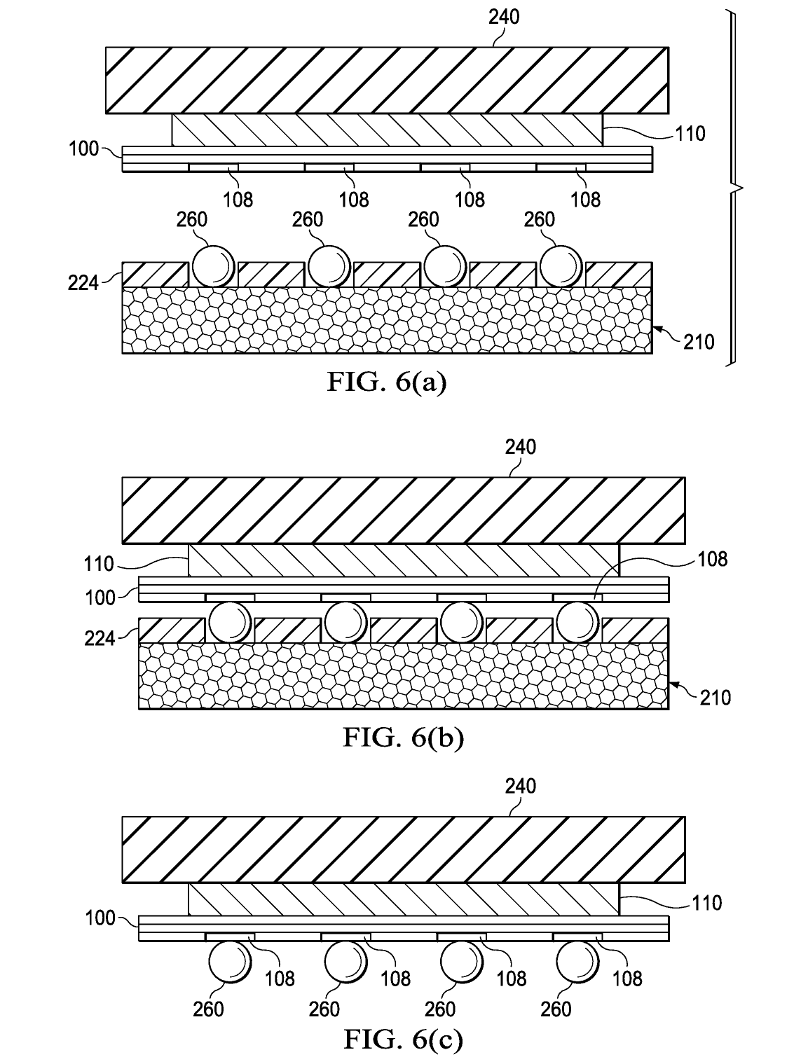

Next, as shown in FIG. 6 (a), the suction plate 240, which holds the resin 110 of substrate 100, is driven by the driving device 250 (Refer to FIG. 3) and lowered in the perpendicular direction toward the base member 210. The substrate 100 is aligned with the second-layer mask 224, and the terminal regions 108 are matched with the through-holes 224a of the second-layer mask.

Next, as shown in FIG. 6 (b), the substrate 100 is pressed against microballs 260 in the perpendicular direction as the suction plate 240 is lowered, and the microballs 260 are transferred to the terminal regions 108 of the substrate 100. The substrate is lowered until the terminal regions 108 of the substrate come into contact with the microballs 260 at a fixed pressure. The microballs 260 are held on the surface 214 until they come into contact with the terminal regions 108. As such, microballs 260 are prevented from rotating inside the through-holes 224a in order to prevent flux or solder paste at the terminal regions 108 from adhering to the inner side of the through-holes 224a. The vacuum stops soon after the microballs 260 come into contact with the terminal regions 108.

In addition, in the event of warping of the substrate 100, because the substrate 100 is pressed against the base member 210 by the suction plate 240 via microballs 260, the wrappage of the substrate 100 is corrected, and the space between the substrate 100 and the second-layer mask 224 becomes uniform, so that the microballs 240 are mounted accurately in the terminal regions 108.

Next, as shown in FIG. 6 (c), the substrate 100, onto which the microballs 260 are transferred, is obtained when the suction plate 240 is raised in the perpendicular direction. The substrate 100, onto which the microballs 240 are transferred, is removed from the microball mounting device and sent to a reflow step. The microballs and the terminal regions form a metallic joined there. Then, cutting into individual units is performed through singulation, whereby a BGA package is created in which microballs or bump electrodes are formed on one side of its substrate.

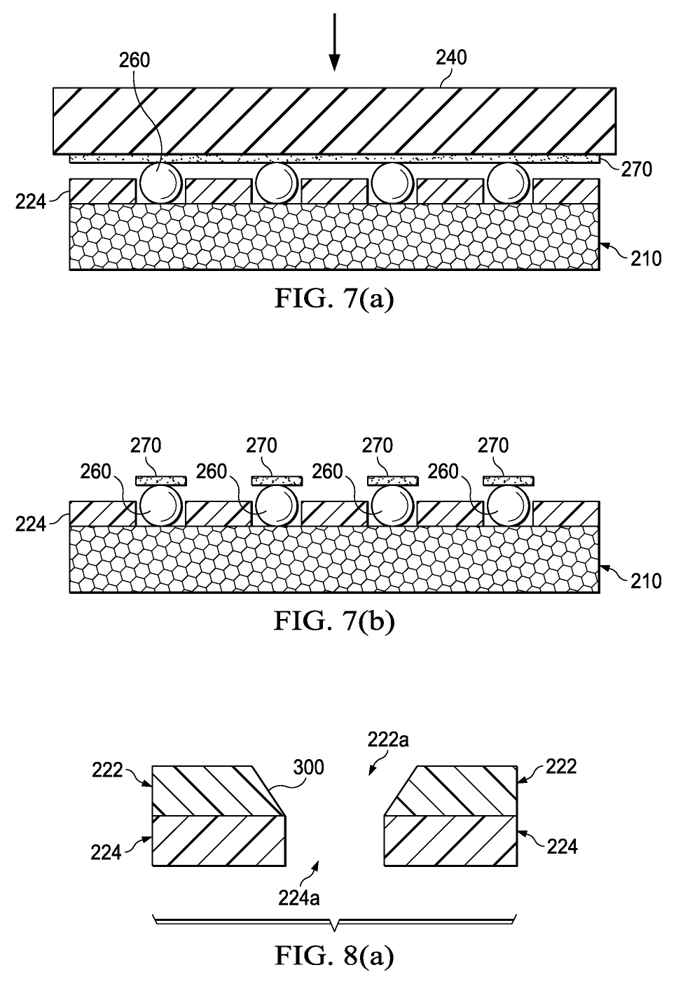

Although a case in which the microballs were transferred onto the substrate was exemplified with reference to the aforementioned method, as shown in FIG. 7 (a) it is also feasible to deposit a flux layer 270 on the suction plate 240, which is lowered in order to press the flux layer 270 against microballs 260. As shown in FIG. 7 (b), flux that came into contact with the microballs 260 is transferred onto the microball side as a result. The microballs, onto which the flux is transferred in this manner, can be mounted in terminal regions 108 of substrate 100 in accordance with the step shown in FIG. 6.

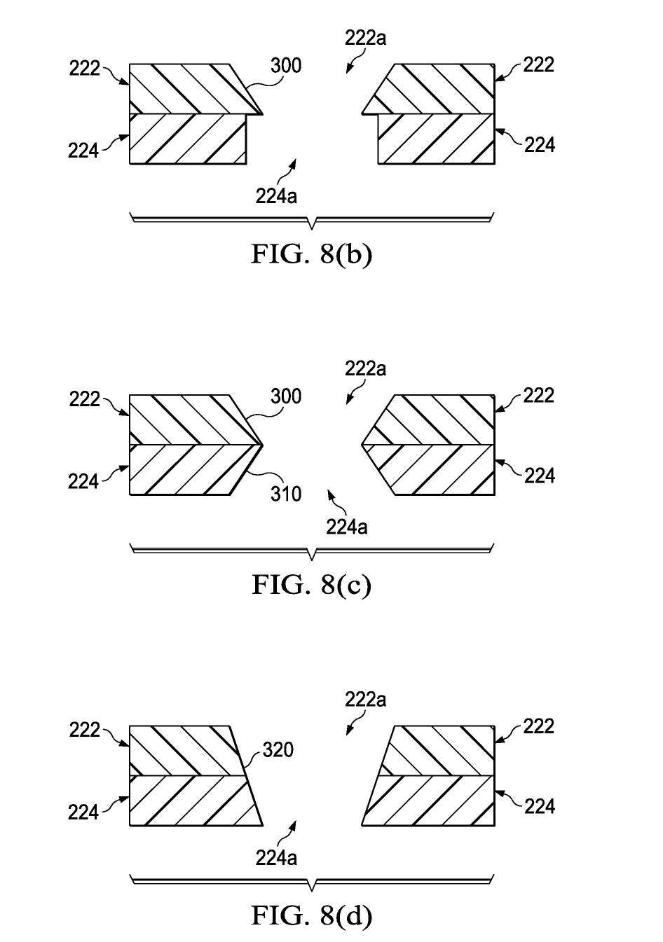

Next, examples of modification of the mask set of the present embodiment will be explained. Although a case was shown in the aforementioned embodiment, in which the diameter D1 of the through-holes 222a of the first-layer mask 222 and the diameter D2 of the through-holes 224a of the second-layer mask 224 were the same, for example, tapered surface 300 may be formed on the through-holes 222a of the first-layer mask 222 so as to lead the microballs more easily, as shown in FIG. 8 (a). Tapered surface 300 may be formed across the entire thickness of the first-layer mask, or it may be formed partially. In addition, as shown in FIG. 8 (b), the diameter D2 of the through-holes 224a of the second-layer mask 224 may be made somewhat larger than the diameter D1 of the through-holes 222a of the first-layer mask 222 in order to improve the holding capability of the base member 210. Furthermore, tapered surface 310 of the second-layer mask may be inverted with respect to tapered surface 300 of the first-layer mask as shown in FIG. 8 (c), or continuous tapered surface 320 may be formed on both the first-layer mask 222 and the second-layer mask 224 as shown in FIG. 8(d).

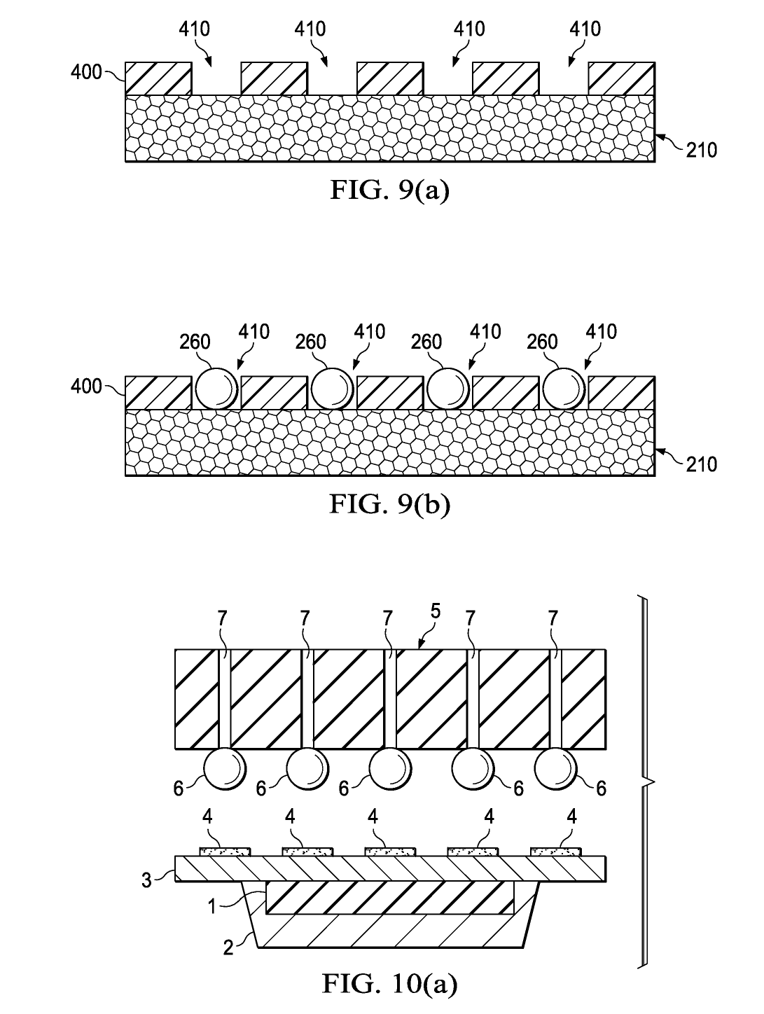

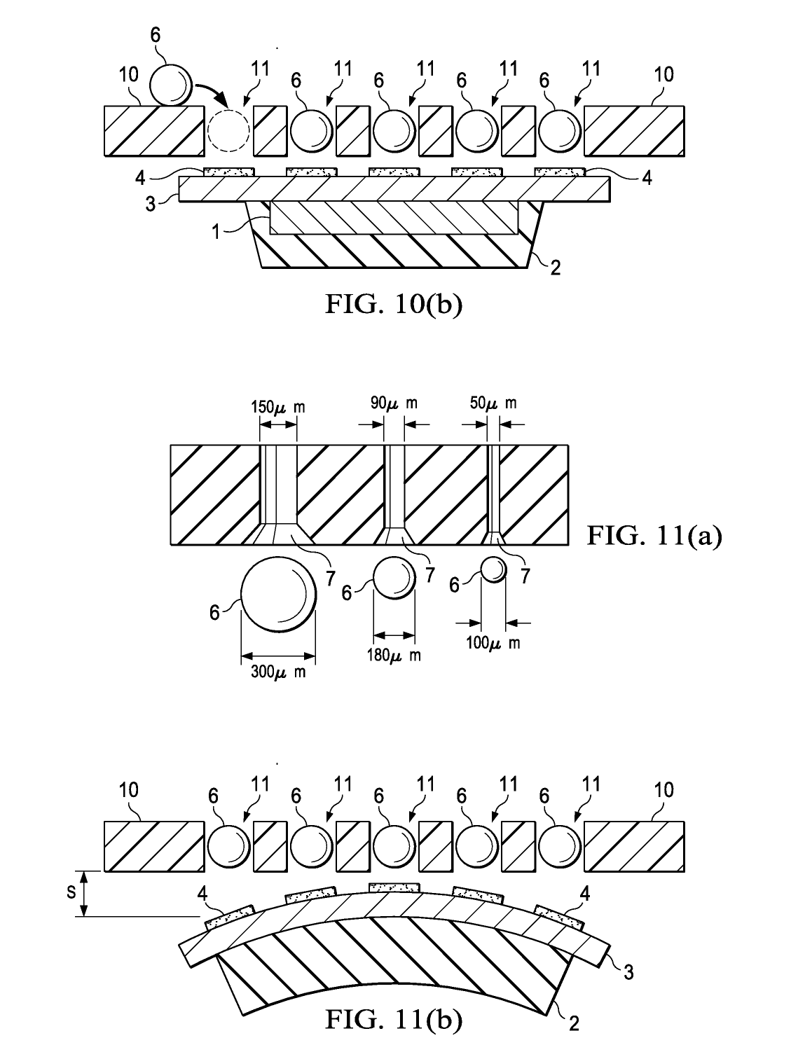

Next, the microball mounting method in accordance with a second embodiment of the present invention will be explained. Although a mask with a 2-layer structure was used as the mask set in the first embodiment, a 1-layer mask is utilized in the second embodiment. As shown in FIG. 9 (a), a mask 400 is fixed onto the base member 210. The mask 400 does not have to be detachable from base member 210. Through-holes 410 are created on the mask 400 in the same pattern as the pattern of terminal regions 108 of the substrate 100.

Next, as shown in FIG. 9 (b), microballs 260 are dropped into the through-holes 410 of mask 400. The dropping of microballs 260 is realized by the suction of the base member 210. In the second embodiment, because the microballs 260 partially protrude from the top surface of the mask 400, a placement member operates in a horizontal direction at a position higher than the diameter of the microballs. Or the placement operation of the microballs using the placement member is omitted. In addition, the base member may be vibrated in order to aid the microballs 260 into the through-holes 410. In a subsequent step, like in the first embodiment, terminal regions 108 of substrate 100 are pressed against microballs 260 so as to transfer microballs 260 onto the substrate. In the second embodiment, because the operation of removing the mask after the microballs are held is no longer needed, the cost of the mask can be reduced, and the microball mounting step can be simplified.

A preferred embodiment of the present invention has been explained above. However, the present invention is not restricted to the specific embodiment pertaining to the present invention, and it may be modified or changed in a variety of ways within the scope of the gist of the present invention described under the Claims.

Although a BGA package was exemplified in the embodiments, the present invention can be applied to a CSP package or other surface-mount type of semiconductor device. In addition, cases involving 1-layer and 2-layer structures were exemplified in the embodiments, a multilayered structure involving 3 or more layers may also be adopted as needed. Furthermore, other than the molding, sealing by means of potting may be utilized for the semiconductor chip mounted on the substrate. Moreover, as cases in which the microballs were mounted on the substrate were exemplified in the embodiment; the present invention can be applied to the mounting of bump electrodes formed on the front surface of a flip-chip type of semiconductor chip.

The conductive ball mounting method and the mounting device pertaining to the present invention can be utilized for manufacturing a surface-mount type of semiconductor device, such as a BGA or CSP.

1. A method for forming a semiconductor device, comprising:
providing a porous base member having a first principal surface and a second principal surface opposite the first principal surface;
placing a mask member with multiple through-holes that is placed on the second principal surface;
applying vacuum or low pressure from the first principal surface of the base member;
supplying to the second principal surface of the mask member by dropping the conductive balls into the through-holes of the mask member;
holding the conductive balls at the second principal surface of the base member, and
pressing the conductive balls against multiple terminal regions formed on a side of a substrate opposite a semiconductor chip.

2. The method of claim 1, wherein the mask member includes a first-layer mask and a second-layer mask, wherein the second-layer mask is placed on the second principal surface of the base member, and the first-layer mask is placed on the second-layer mask; and wherein the conductive balls are placed below a top surface of the first-layer mask; wherein the conductive balls are partially exposed from the second-layer mask when the first-layer mask is removed from the second-layer mask; and wherein the conductive balls exposed from the second-layer mask are pressed against the terminal regions formed on the substrate.

3. The method of claim 1, further comprising transferring flux to the surfaces of the conductive balls.

4. The method of claim 1, wherein the semiconductor chip is electrically connected to the terminal regions and is sealed with a resin.

5. The method of claim 2, wherein a tapered surface is formed on the through-holes of the first-layer mask.

6. The method of claim 5, wherein the through-holes of the first-layer mask have a diameter D1; the through-holes of the second-layer mask have a diameter D2; and D1 is greater than D2.

7. The method of claim 2, wherein the first-layer mask has a thickness T1; the second-layer mask has a thickness T2; and the conductive balls have a diameter D; and the sum of T1 and T2 is greater than D.

8. The method of claim 1, further comprising a step of reflowing the conductive balls.

9. A semiconductor device that has conductive balls mounted using the method of claim 1.

10. A conductive ball mounting device comprising:
a porous base member having a first principal surface and a second principal surface opposite the first principal surface,
a suction means that applies suction from the first principal surface,
a mask member placed on the second principal surface with multiple through-holes exposing a portion of the second principal surface of the base member,
a retaining means for retaining a substrate having multiple terminal regions formed on one side,
conductive balls; and
a pressing means for moving the retained substrate toward the base member in order to press the conductive balls held inside of the through-holes on the second principal surface of the base member, against the terminal regions on the substrate.

11. The conductive ball mounting device of claim 10, wherein the mask member includes a first-layer mask and a second-layer mask, wherein the second-layer mask is placed on the second principal surface of the base member, and the first-layer mask is placed on the second-layer mask; wherein the conductive balls are below a top surface of the first-layer mask; and wherein the conductive balls are partially exposed from the second-layer mask when the first-layer mask is removed from the second-layer mask.

12. The conductive ball mounting device of claim 11, wherein the through-holes of the first-layer mask have tapered surface.

13. The conductive ball mounting device of claim 12, wherein when the through-holes of the first-layer mask have diameter D1; and the through-hole of the second-layer mask have diameter D2; and D1 is greater than D2.

14. The conductive ball mounting device of claim 11, wherein the first-layer mask has a thickness T1; the second-layer mask has a thickness T2; the conductive balls have a diameter D; and the sum of T1 and T2 is greater than D.
